(19) United States
(12) Patent Application Publication
(10) Pub. No.: US 2026/0225874 A1
(43) Pub. Date: Aug. 6, 2026

(54) MEMS COMPRISING A COMB DRIVE, AND METHOD FOR PRODUCING SAME

(71) Applicant: Fraunhofer-Gesellschaft zur Förderung der angewandten Forschung e.V., München (DE)

(72) Inventors: Anton MELNIKOV, Dresden (DE); Bert KAISER, Dresden (DE)

(73) Assignee: Fraunhofer-Gesellschaft zur Förderung der angewandten Forschung e.V., München (DE)

(21) Appl. No.: 19/635,646

(22) Filed: Mar. 31, 2026

Related U.S. Application Data
(63) Continuation of application No. PCT/EP2024/077815, filed on Oct. 2, 2024.

(30) Foreign Application Priority Data
Oct. 5, 2023 (DE) 102023209764.8

(51) Int. Cl. B81B 3/00; B81C 1/00

(52) U.S. Cl. CPC B81B 3/004; B81C 1/00682; B81B 2201/0257; B81B 2203/0136; B81B 2203/04

(57) ABSTRACT

An MEMS includes a comb drive having a first finger structure including a first plurality of electrode fingers and a second finger structure including a second plurality of electrode fingers forming an interlaced arrangement in parallel to a substrate plane of the MEMS. The comb drive is configured to provide a translational relative movement between the first finger structure and the second finger structure based on an electrostatic force for changing a distance between the first finger structure and the second finger structure in parallel to the substrate plane. The first plurality of electrode fingers and the second plurality of electrode fingers are curved perpendicular to the substrate plane.

### CROSS-REFERENCE TO RELATED APPLICATIONS

This application is a continuation of copending International Application No. PCT/EP2024/077815, filed Oct. 2, 2024, which is incorporated herein by reference in its entirety, and additionally claims priority from German Application No. 102023209764.8, filed Oct. 5, 2023, which is also incorporated herein by reference in its entirety.

The present invention relates to an MEMS having a comb drive comprising curved electrode fingers. Further, the present invention relates to a method for producing such an MEMS and in particular to a comb drive having an optimized non-linear behavior.

### BACKGROUND OF THE INVENTION

Micro-electromechanical systems, MEMS, can be implemented, among others, for actuator operation and/or sensor operation. For actuator operation, power members can be provided that provide power for generating a signal and/or a movement. In that way, a movement can be provided within an MEMS, for example, by a comb drive, wherein electrode fingers of finger structures that are moveable relative to each other interdigitate and, based on electrostatic forces, an electrostatic force for providing the relative movement is generated between the finger structures.

The usage of such a comb drive is described, for example, in WO 2021/223886 A1, see, for example, FIG. 12a-d. In the document, an installation space-efficient MEMS is described.

WO 02/19509 A2 describes a comb drive arrangement with comb drive fingers having irregular cross-sections increasing the ratio of the driving force per applied voltage. Increasing the driving force due to the geometry of the comb drive fingers is obtained without having to increase the voltage. In the top view, comb drive fingers can be formed as wedge-shaped structures, above that, the comb drive fingers comprise, in the top view, truncated structures. It is a disadvantage that no change of the counter force by the movement due to the finger forces is considered, in other words, the force path is continuous but is not adapted to a characteristic curve of the counter force.

US 2016/268927 A1 describes a comb drive apparatus with comb fingers that are not formed in parallel, which is supposed to be suitable for linearizing the capacity between respective comb finger gaps during an arched movement. It is a disadvantage that no change of the counter force by the movement due to finger forces is considered and the same is not adapted to the characteristic curve of the counter force.

DE 10 2017 206 183 A1 describes rectangular comb drives as MEMS actuators. It is the disadvantage of this structure that the course of the finger shape does not have any influence on the force characteristic.

US 2013/009716 A1 describes an MEMS resonator with comb electrodes. Here, a course of the finger shape is also not adapted to the force characteristic.

It is a disadvantage of the previously known solutions that the rigidity of the deformable elements is non-linear relative to the transmission behavior. Due to the non-linearities, in an exemplary audio application of the MEMS, higher harmonics are generated during harmonic excitation, which result in disadvantageous distortions of the audio signal.

Thus, MEMS having comb drives showing a linearized behavior of the force deflection curve would be desirable.

### SUMMARY

According to an embodiment, an MEMS may have: a comb drive having a first finger structure including a first plurality of electrode fingers and having a second finger structure including a second plurality of electrode fingers that form an interlaced arrangement with the first plurality in parallel to a substrate plane of the MEMS; wherein the first plurality of electrode fingers and the second plurality of electrode fingers are curved perpendicular to the substrate plane; and wherein an electrode finger of the first finger structure or the second finger structure comprises an undercut in a plane perpendicular to the substrate plane, starting from a first electrode finger end toward a second opposite electrode finger end.

According to another embodiment, a method for producing an MEMS may have the steps of: arranging a comb drive having a first finger structure including a first plurality of electrode fingers and having a second finger structure including a second plurality of electrode fingers, such that the first plurality of electrode fingers and the second plurality of electrode fingers form an interlaced arrangement with the first plurality in parallel to a substrate plane of the MEMS; such that the first plurality of electrode fingers and the second plurality of electrode fingers are curved perpendicular to the substrate plane; such that an electrode finger of the first finger structure or the second finger structure comprises an undercut in a plane perpendicular to the substrate plane, starting from a first electrode finger end toward a second opposite electrode finger end.

It is a core idea of the present invention to provide a comb drive for translational movement, wherein electrode fingers of both interdigitating finger structures are formed in a curved manner in the top view, i.e., in parallel to the substrate plane of the MEMS. By the respective curvatures, adaptation of the force deflection behavior is possible. In contrary to WO 02/19509 A2 and US 2016/268927 A1, both sides of the comb drive are formed in a curved manner and at the same time, a translational movement, i.e., a movement directed straight toward each other is implemented.

According to an embodiment, an MEMS is provided, which comprises a comb drive having a first finger structure including a first plurality of electrode fingers and having a second finger structure including a second plurality of electrodes that form an interlaced arrangement in parallel to a substrate plane of the MEMS. The comb drive is configured to provide a translational relative movement between the first finger structure and the second finger structure based on an electrostatic force for changing a distance between the first finger structure and the second finger structure in parallel to the substrate plane. The first plurality of electrode fingers and the second plurality of electrode fingers are curved perpendicular to the substrate plane. Advantageously, this allows the adaptation of a force deflection curve.

According to an embodiment, an electrode finger of the first finger structure and/or the second finger structure is formed such that an undercut is arranged in a plane perpendicular to the substrate plane, starting from a first electrode finger toward a second opposite electrode finger. In connection with the translational movement, the undercut allows a particularly exact and advantageous adaptation of the force deflection curve.

According to an embodiment, sides of interdigitating electrode fingers that are facing each other are formed congruently at least within an operating range. This allows a further optimization of the force deflection curve. A congruent configuration of side faces that are facing each other can also take place independently of the undercut.

According to an embodiment, a side face of an electrode finger of the first finger structure or the second finger structure comprises a concave portion, starting from a first electrode finger toward a second opposite electrode finger. Regarding its radius, the concave portion can allow a good adjustment option of the deflection behavior of the comb drive.

According to an embodiment, the concave portion is shaped such that a curvature having a radius is provided, wherein the radius differs from a curvature of the electrode finger at a free end of the electrode finger.

According to an embodiment, the concave portion is arranged between a first side wall portion of the electrode finger and a second side wall portion of the electrode finger. Starting from a clamped end of the electrode finger, the first side wall portion is inclined at a first angle relative to a main extension direction of the electrode finger. The second sidewall portion of the electrode fingers is inclined at a second angle relative to the main extension direction of the electrode finger toward a free end of the electrode finger. The first angle has the value of 30 degrees at most and the second angle has a value of 45 degrees at most. These values result in a particularly high measure of linearity of the deflection behavior.

According to an embodiment, at least one of the electrode fingers comprises a combination of an undercut of a non-clamped side of the electrode finger and a broadening of the electrode finger at a clamped side of the electrode finger. This allows an adaptation by means of the broadening of the electrode finger at the clamped end at an undercut of an opposite electrode finger.

According to an embodiment, the at least one electrode finger comprises a greater electrode finger width on the clamped side compared to the non-clamped side.

According to an embodiment, a wave-shaped recess is arranged between a first side face of a first electrode finger of the first finger structure and a second side face of a second electrode finger of the second finger structure facing the first side face. A waveform allows a compensation of mechanical non-linearities.

According to an embodiment, a curvature of curved electrode fingers is adapted to a non-linear rigidity of the comb drive, wherein a curvature-based force variation in the comb drive and along a direction of movement of the comb drive compensates a deflection-based rigidity variation of the comb drive within a tolerance range. Thereby, the force deflection curve can be optimized.

According to an embodiment, based on the curvature of curved electrode fingers, the MEMS is configured such that a linearized ratio between deflection of the comb drive and generated electrostatic force of the comb drive is obtained, which allows precise control of the MEMS.

According to an embodiment, the first finger structure and the second finger structure form a first structure pair. The MEMS comprises at least one further structure pair connected in series to the first structure pair along a force direction of the comb drive. This allows an increase of the generated force in the comb drive.

According to an embodiment, the MEMS is configured such that, starting from a curved area of the electrode finger, an essentially rectangular area is arranged toward a free end or a clamped end.

According to an embodiment, the MEMS is configured as loudspeaker. Such a loudspeaker can reproduce high-quality audio signals, for example, by suppressing harmonic interferences due to the obtained linearity.

According to an embodiment, a method for producing an MEMS includes arranging a comb drive having a first finger structure including a first plurality of electrode fingers and having a second finger structure including a second plurality of electrode fingers, such that the first plurality of electrode fingers and the second plurality of electrode fingers form an interdigitated arrangement with the first plurality in parallel to a substrate plane of the MEMS. The method is performed such that the first plurality of electrode fingers and the second plurality of electrode fingers are curved perpendicular to the substrate plane; and such that an electrode finger of the first finger structure or the second finger structure comprises an undercut in a plane perpendicular to the substrate plane, starting from a first electrode finger toward a second opposite electrode finger end.

### BRIEF DESCRIPTION OF THE DRAWINGS

Embodiments of the present invention will be detailed subsequently referring to the appended drawings, in which:

FIG. 1a is schematic top view of a comb drive according to an embodiment;

FIG. 1b is an enlarged illustration of part of a comb drive of FIG. 1a;

FIG. 2 is a schematic exemplary diagram of a driving structure according to an embodiment having two comb drives connected in series one after the other, in order to allow active deflection along positive and negative y-directions;

FIG. 3 is a schematic top view of part of an electrode finger according to an embodiment that can be used, for example, as electrode finger according to FIGS. 1a and 1b;

FIG. 4 is a schematic top view of a comb drive according to an embodiment wherein the serial connection of at least two comb drives one after the other is illustrated schematically along the force direction;

FIG. 5 is a schematic block diagram of a comb drive according to an embodiment in a top view, wherein in contrast to the symmetrical arrangement in FIG. 4, an asymmetrical arrangement is illustrated;

FIG. 6 is a schematic illustration of an electrode finger according to an embodiment wherein the approximated shape of the electrodes is implemented as steps;

FIG. 7a is a schematic top view of an electrode finger according to an embodiment with an extension at a clamped end;

FIG. 7b is a schematic top view of an electrode finger according to an embodiment with an extension at a free end; and

FIG. 8 is a schematic flow diagram of a method according to an embodiment.

### DETAILED DESCRIPTION OF THE INVENTION

Before embodiments of the present invention will be discussed in more detail based on the drawings, it should be noted that identical, functionally equal or equal elements, objects and/or structures are provided with the same reference numerals in the different figures, such that the description of the elements illustrated in different embodiments is interexchangable or interapplicable.

Embodiments described below are described in the context of a plurality of details. However, embodiments can also be implemented without these detailed features. Further, embodiments are described, for improved understanding, by using block diagrams replacing a detailed representation. Further, details and/or features of individual embodiments can easily be combined with each other as long as it is not explicitly stated otherwise.

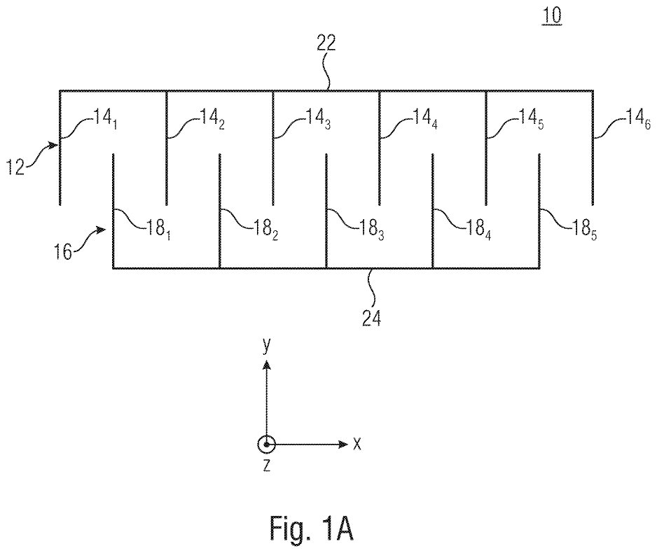

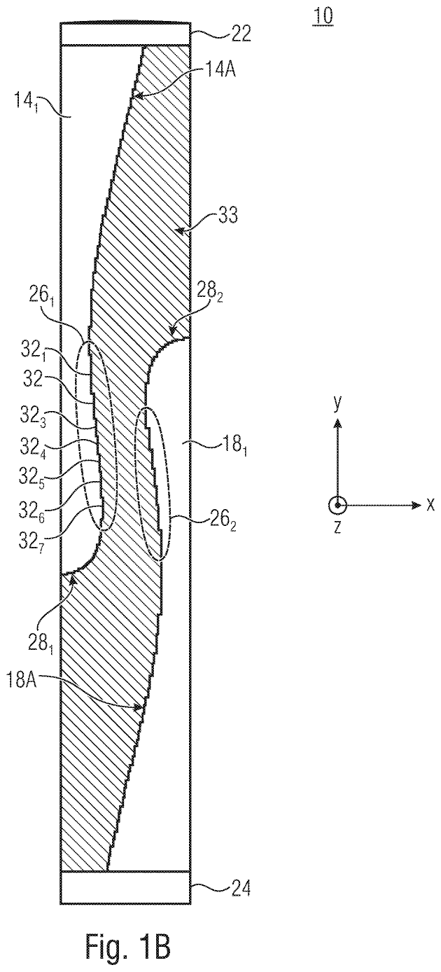

FIG. 1a shows a schematic top view of a comb drive 10 according to an embodiment, wherein some of the details of the comb drive 10 are shown in FIG. 1b. The comb drive 10 comprises a first finger structure 12 having a plurality of electrode fingers 14₁-14₆, wherein a plurality of electrode fingers 14 of the finger structure 12 can comprise any value of at least 2, such as 3, 4, 5, 6, 10 or more, such as at least 15, at least 20 or more.

Further, the comb drive 10 comprises a second finger structure 16 having a plurality of electrode fingers 18₁-18₅ in a number that is the same or differing from the finger structure 12. The finger structures 12 and 16 can be arranged completely or partly in parallel to a substrate plane of the comb drive or an MEMS comprising the comb drive 10. This means, starting from one of the two finger structures 12 or 16, the other finger structure 16 or 12 can be arranged in parallel to an y-direction in parallel to the substrate plane. The fingers 14₁-14₆ on the one hand and 18₁-18₅ on the other hand can form an interdigitated arrangement, this means one electrode finger of the other electrode structure 16 or 12 can each be arranged between two electrode fingers of a finger structure 12 or 16. A potential difference between electrode fingers of the first finger structure 12 and electrode fingers of the second finger structure 16 can effect an electrostatic force resulting in a translation movement along the y-direction between the finger structures 12 and 16 relative to each other.

The electrostatic force can be used for changing a distance between the finger structures 12 and 16 in parallel to the substrate plane along the y-direction.

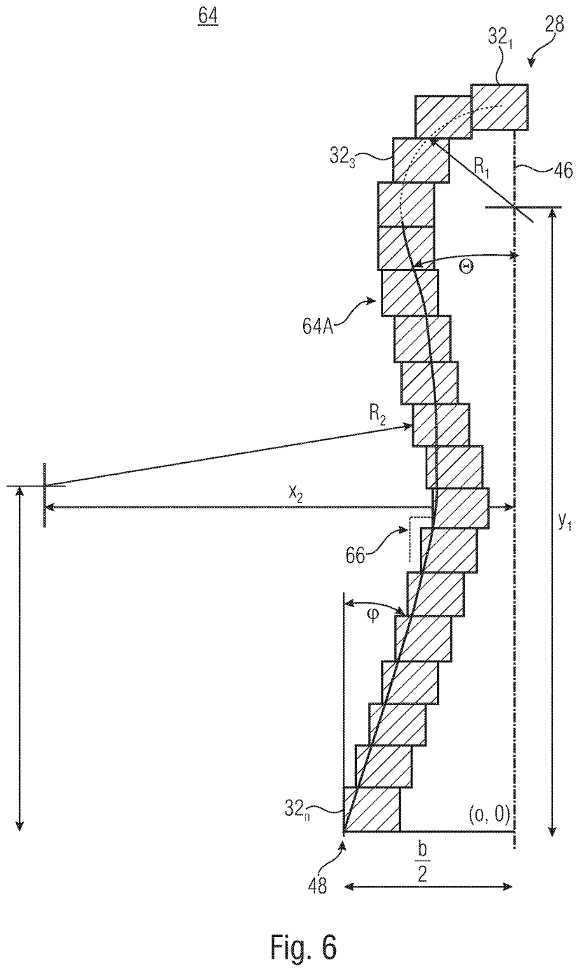

FIG. 1b shows an increased illustration of part of a comb drive 10 of FIG. 1a. Here, it is shown that the first plurality of electrode fingers 14 and the second plurality of electrode fingers 18 are curved perpendicular to the substrate plane x/y. This can be considered such that main sides 14A and 18A of the electrode finger 14₁ and 14₂, which can be arranged perpendicular to the substrate plane x/y, are formed in a curved manner, in particular, with a course along the y-direction. A recess 33 between the side faces 14A and 18A can be wave-shaped, wherein, independent on the geometry of the electrode fingers, at least in the shown top view in some embodiments, the waveform can be deviated from, in particular, a continuous waveform, see for example FIG. 6.

The y-direction can be considered as main extension direction of the electrode fingers starting from mounts 22 of the first finger structure 12 or 24 of the second electrode structure 16. The curvature can be illustrated in the projection of the electrode fingers 14₁ and 18₁ in a plane parallel to the substrate plane. Further additional curvatures, such as relative to an y/z plane which cannot be seen in the view illustrated in FIG. 1b are not excluded. In other words, at least one electrode finger or at least one side or surface facing an adjacent electrode finger comprises a curved course.

The curvatures of the main sides 14A and 14B at least in main side portions of the electrode fingers 14₁ and 18₁ will be explained in detail below. The respective parametrizations can be implemented independent of each other but also in combination with each other. Here, the described adaptations of the curvatures relate in particular to an operating range of the electrode fingers 14₁ and 18₁ or the finger structures 12 and 16. In the context of embodiments described herein, an operating range means a deflection range of the comb drive 10 within which the areas of the electrode fingers shift relative to each other and the main sides are arranged facing each other. For example, for preventing mechanical contact of one electrode finger 14 with an opposite mounting area 24 or an electrode finger 18 with an opposite mounting area 22, a remaining distance can be provided that has the effect that no overlapping with an adjacent electrode finger takes place in parts of the electrode fingers adjacent to the mounts 22 and/or 24. Here, optimizations can be omitted, without causing a negative effect on the adaptation of the deflection behavior described herein.

Some of the embodiments described herein relate to MEMS having a comb drive, wherein one or several electrode fingers of the finger structure 12 and/or 16 comprise an undercut 26₁ or 26₂ in a plane perpendicular to the substrate plane, starting from a first electrode finger end, such as adjacent to the mounting area 22 or 24, toward an opposite second electrode finger end, such as the moveable or deflectable end. An undercut 26₁ or 26₂ can be considered such that removing the structure from an integral forming tool, such as when considering an injection mould method, in parallel to the y-direction is prevented. Thus, for example, the broadening toward the movable or free end 28₁ obtained by the undercut or undercut 26₁ can prevent removal from the moulding tool along the positive y-direction. Also, removing the electrode finger 18₁ along the negative y-direction can be prevented due to the broadening toward the free end 282.

One shape or geometry of the electrode finger and/or the undercut 26₁ and/or 26₂ can have a continuous shape, but can also have an essentially rectangular form or a combination of several essentially rectangular shapes, such as illustrated, for example, by steps 32₁-32₇. The step shape allows a good compatibility with etching processes, wherein it is possible but not needed to provide rectangular angles between steps 32₁-32₇. As discussed based on FIG. 6, typical sizes of an obtained step shape can be obtained in the range of 300 nm or more, such as up to approximately 5 μm. Alternatively, an essentially continuous shape can be implemented.

Independent of but also in combination with the undercuts 26₁ or 26₂, the sides 14A and 18A of the interdigitated electrode fingers 14₁ and 18₁ that are facing each other can be formed congruently. This means the main side 14A can be congruent with the side 18A, at least when considering the operating range at a rotation of 180 degrees around the z-axis, possibly with additional translational displacement.

In other words, FIG. 1b shows a comb drive optimized regarding the elimination/reduction of the non-linear transmission portions of a microbeam and/or membrane.

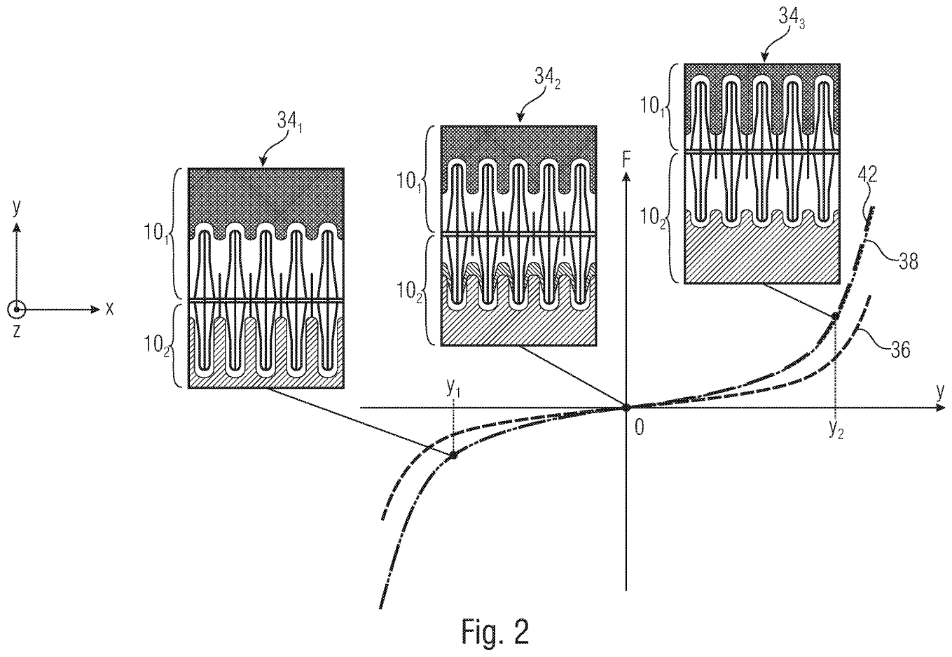

FIG. 2 shows a schematic exemplary diagram of a driving structure having two comb drives 10₁ and 10₂ that are connected in series one after the other to allow an active deflection along the positive and negative y-direction. Thus, exemplarily, three states 34₁, 34₂ and 34₃ are illustrated, wherein in the state 34₁ a comb drive structure 10₂ is activated and a distance of the electrode fingers is small to minimum, while the electrode fingers in the comb driving structure 10₁ have an increased distance. A state 34₂ comprises a reference state, such as without actuation, which can correspond to the zero point on an y-axis. A state 34₃ corresponds to a state inverted relative to state 34₁, wherein the comb driving structure 10₁ is activated, whereby a deflection y2 of the comb driving structure is obtained, which can be opposite to a deflection y1 of the state 34₁.

The diagram shows an exemplary course of a Coulomb force of an exemplary non-optimized structure. Here, non-optimized can mean the interaction of force path of the drive and counter-force/restoring force of the mechanics. Further, this can mean that this is an obvious geometric deflection. According to conventional technology, such an obvious implementation is a straight course of the finger electrode edges, in particular without undercut.

In contrast, a curve 38 shows a Coulomb force of the comb drives optimized by means of the curvatures and electrode finger geometries described herein, which can be adapted to a non-linear rigidity 42 of the mechanical system due to the adaptation of the electrode finger curvature. This means, by the curvature, an adaptation of the electrode fingers can take place such that the Coulomb force 38 corresponds to the non-linear rigidity, which allows a linearization of the force deflection curve overall.

The superposition of the curves 38 and 42 illustrates an embodiment wherein a curvature of curved electrode fingers is adapted to a non-linear rigidity of the comb drive and compensates a curvature-based force variation in the comb drive and a deflection-based rigidity variation of the comb drive along a direction of movement of the comb drive within a tolerance range of less than 20%, less than 10% or less than 5%. According to such an embodiment, curved electrode fingers can have a linearized ratio between deflection of the comb drive and generated electrostatic force of the comb drive. Linearization is shown in that the curve 42 and curve 38 are illustrated congruently. This results in a linearity for the system behaviour, which can also be considered such that for the same change in path (y) the same response in force (F) is obtained, both in drive or deflection and reset.

In other words, FIG. 2 shows a deformable element having a geometry deviating from a rectangle and a force-displacement course matching the non-linearity of a microbeam.

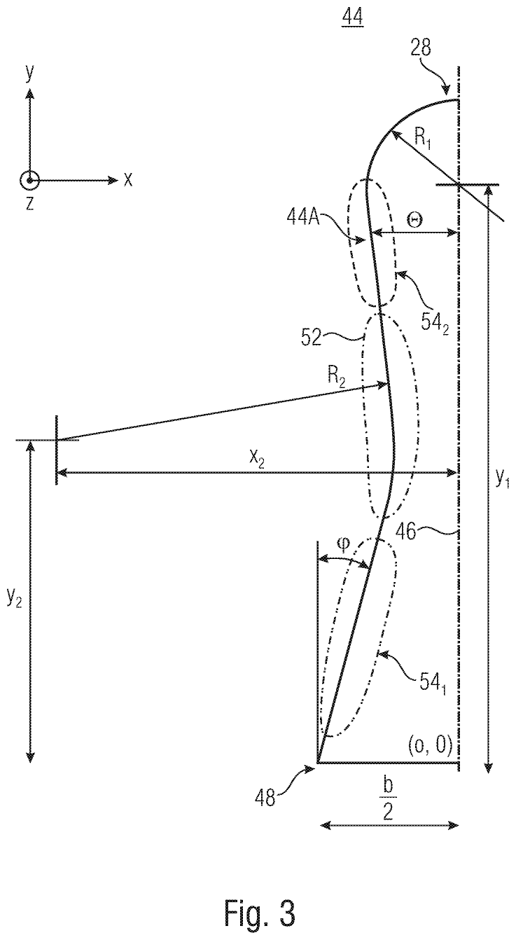

FIG. 3 shows a schematic top view of a part of an electrode finger 44 according to an embodiment, which can be used, for example, as electrode finger 14 and/or electrode finger 18. The configuration parameters described herein can be implemented independent of each other or also in combination. FIG. 3 merely shows part of the electrode finger 44 that is divided along an intersection axis 46. Along the x-direction, the electrode finger 44 can be mirror-symmetrical or can deviate from a mirror symmetry, which can depend on the respective adjacent and opposite electrode fingers associated with the opposite finger structure.

A side face 44A of the electrode finger 44 can comprise a concave portion 52 starting from a clamped end 48 toward an unclamped or free end 28. The concave portion 52 can include a curvature having a radius R2, which differs from a curvature R1 of the electrode finger 44 at the free end 28. Advantageously, the radius R2 is greater than the radius R1.

The concave portion 52 can be arranged between sidewall portions 54₁ and 54₂. Starting from the clamped end 48 toward the free end 28, the sidewall portion 54₁ can be arranged in front of the sidewall portion 54₂. The first sidewall portion 54₁ can be inclined at an angle φ relative to the main extension direction y of the electrode finger 44. The second sidewall portion 54₂ of the electrode finger can be inclined at an angle θ toward the free end 28 of the electrode finger relative to the main extension direction 28 of the electrode finger. The angle φ has a value of 30 degrees at most and the angle θ a value of 45 degrees at most. Within the structure, the following can apply:

$$For {y}_{1} : {y}_{1} > y 2$$

$$For {y}_{2} : 0 < {y}_{2} < Finger length or overall dimension along y$$

$$For {x}_{2} : {x}_{2} > {R}_{2}$$

$$For b : b > 0$$

$$For {R}_{1} : {R}_{1} > 0$$

$$For {R}_{2} : {R}_{2} > 0$$

In other words, the angles θ and φ can be selected such that the courses of the Coulomb force and the restoring force have similar values, advantageously as close to each other as possible or approximately correspond to each other. Here, the angle at the undercut can be configured such that the same is in a range of 0 degrees<θ≤30 degrees, advantageously 0.5 degrees≤θ≤10 degrees and the angle at the fixed side with the substrate is in a range of 0 degrees<φ≤45 degrees, advantageously 1 degrees≤φ≤15 degrees.

The contour illustrated in FIG. 3 can be structured in a geometrical/parametrical manner or can also be approximated approximately by splines or the same, such as within a design process to subsequently allow implementation by etching out and/or growth. FIG. 3 also illustrates that both the arrangement of an undercut discussed in FIG. 1b and a broadening of the electrode finger are executed at the clamped end.

According to embodiments, the electrode finger 44 can have a larger electrode finger width, i.e., a dimension along the x-direction, at the side 48 clamped to the substrate than on the non-clamped free side 28.

In other words, FIG. 3 shows a deformable element with an undercut at the freely movable side and a broadening on the side connected to the substrate, wherein an angle θ>0 and φ>0 is provided. A configuration according to such an embodiment can also be implemented such that the base of the finger is essentially straight and the broadening at the tip of the finger is greater than the thick/width of the finger at the base, i.e., the clamping.

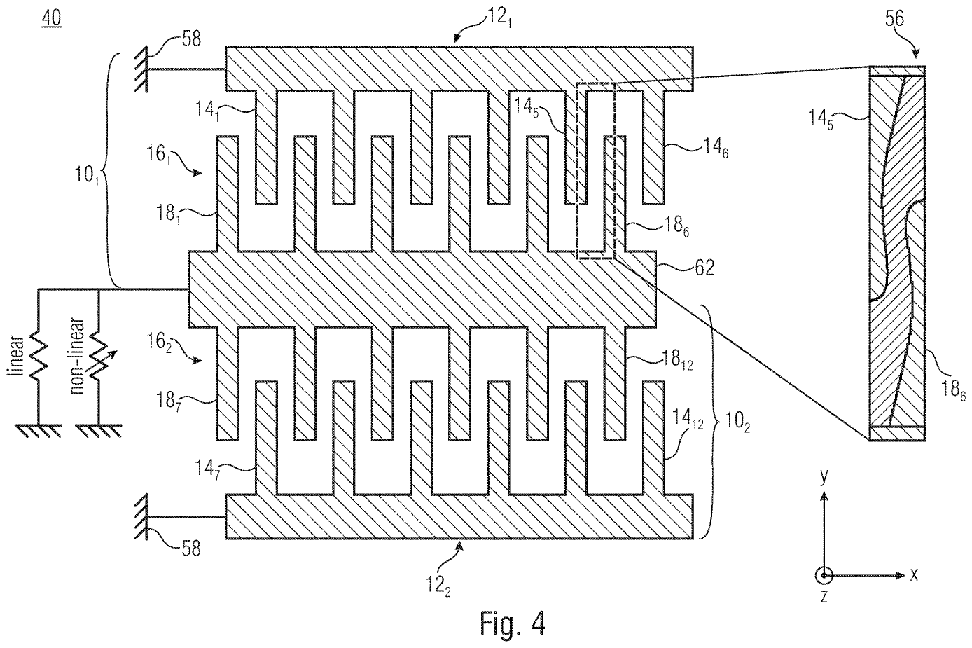

FIG. 4 shows a schematic top view of a comb drive 40 according to an embodiment, wherein the serial connection of at least two comb drives 10₁ and 10₂ is illustrated schematically along the force direction y, which has already been discussed in FIG. 2. Here, the illustration of the electrode fingers 14 and 18 is rectangular as an example, wherein the electrode fingers are actually formed in correspondence with the comb drive 10, as illustrated by the section 56 implemented in correspondence with FIG. 1b.

The electrode finger structures 12₁ and 12₂ of the comb drives 10₁ and 10₂ can, for example, be arranged comparatively immobile along a substrate 58. In contrast, the finger structures 16₁ and 16₂ can be arranged movably and can form a common movable element 62 or be part thereof in a configuration. The finger structures 12₁ and 16₁ can form a first structure pair, wherein at least one further structure pair including the finger structures 12₂ and 16₂ can be arranged, which is connected in series to the first structure pair along the force direction y of the comb drive 40. By controlling the comb drive 40 and the symmetrical arrangement of the structure pairs along the force direction, a particularly advantageous movement can be obtained. Optionally, further comb drives 10 and/or 40 can be connected in series or in parallel. The mechanical components can provide both linear influences and non-linear influences. These influences relate to mechanical components. For example, linear elements can provide a constant non-variable increase of a ratio of force F and deflection y, dF/dy and vice versa, while non-linear elements can provide a variable increase.

In other words, FIG. 4 shows an optimized deformable element embedded in a symmetrical push-pull arrangement.

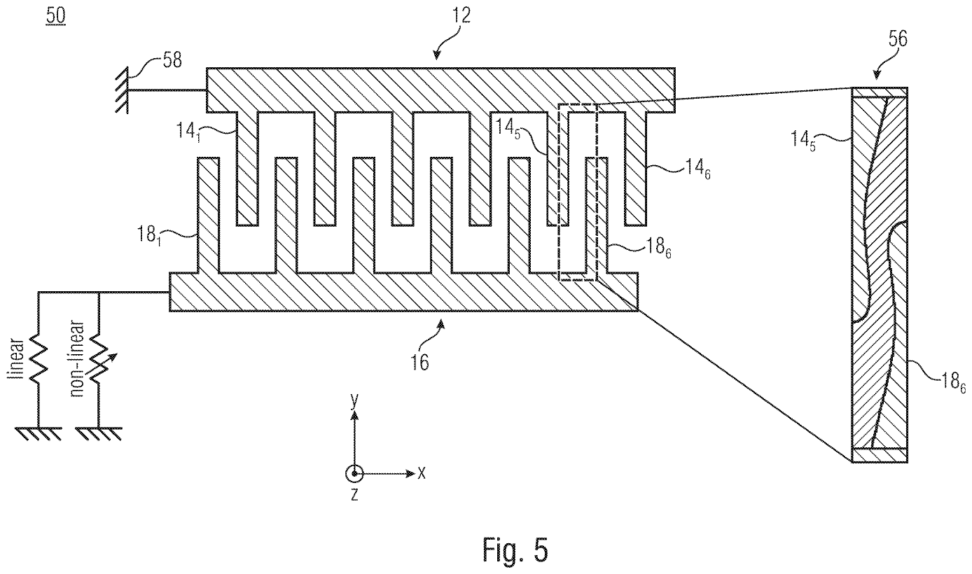

FIG. 5 shows a schematic block diagram of a comb drive 50 according to an embodiment in a top view, wherein, compared to the symmetrical arrangement in FIG. 4, an asymmetrical arrangement of the finger structure 16 arranged moveable relative to the finger structure 12 is illustrated. Here, the presumably rectangular shape of the electrode fingers 14 and 18 is actually curved as indicated by section 56.

In other words, FIG. 5 shows an optimized deformable element embedded in an asymmetrical arrangement.

FIG. 6 shows a schematic illustration of an electrode finger 64 according to an embodiment, wherein the approximated shape of the fingers or electrodes is configured as steps 32. Even when the step elements 32 are merely illustrated such that the same form a sidewall 64A, the electrode finger 64 is not necessarily formed in a hollow manner or in a manner comprising a cavity, but a solid body according to embodiments. At least in the area of the undercut, but possibly also in the further course or in other areas of the electrode finger 64, the electrode finger 64 can comprise one or several rectangular shapes. Several rectangular shapes can form a step shape, wherein a step height of the step shape within the step shape is constant or variable and can have, for example, a value of at least 100 nm to up to several μm. The steps do not necessarily have to be arranged discontinuously or at a right angle to each other, but can have, for example due to etching processes, a curvature between adjacent steps, which can have, for example, a radius of at least 200 nm or 300 nm up to approximately 500 μm.

This means the electrode finger shape of the electrode fingers 44 can be approximated by one or several rectangular shapes.

In other words, FIG. 6 shows an approximated shape with steps.

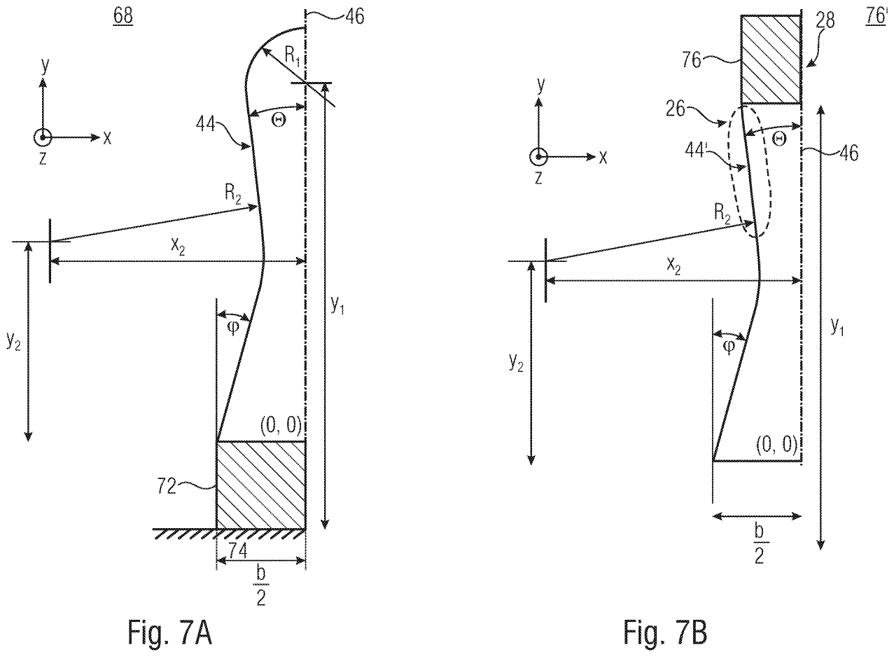

FIG. 7a shows a schematic top view of an electrode finger 68 according to an embodiment that can be used as electrode finger of the first finger structure 12 and/or the second finger structure 16, wherein in correspondence with FIG. 3 and FIG. 6 merely half of the electrode finger is illustrated. The electrode finger 68 can comprise the electrode finger 44 of FIG. 3 or a shape derived therefrom and can be arranged at an extension 72 which is formed in a rectangular or square manner, from which the electrode finger 44 originates along the main extension direction y. The extension 72 can provide an intermediate portion relative to the electrode fingers 14 and/or 18 relative to the substrate or mounts 22 or 24, such as outside an operating range of the electrode fingers. This means, between a mount 74 of the finger structure and curved or at least approximated to a step shape and/or undercuts, a portion of the electrode finger 68 can be arranged that has a rectangular or square cross-section in x/z plane and can possibly have an invariable cross-section along the y-direction.

FIG. 7b shows a schematic top view of an electrode finger 76, wherein a portion 76 starting from the undercut 26 can have a square shape, as described for the extension 72. This can prevent, for example, a curvature at the free end 28, which can be advantageous, for example in the case of a mechanical contact with another element. In this configuration, the extension 72 can also be arranged within the operating range of the comb drive.

In other words, the geometry of the electrode fingers 76′ can transition into a rectangular shape, starting from the undercut 26. For this, FIG. 7a and FIG. 7b show a finger that transitions into a rectangular shape at one of each end. These configurations can easily be combined such that an extension can be arranged on both ends of the finger.

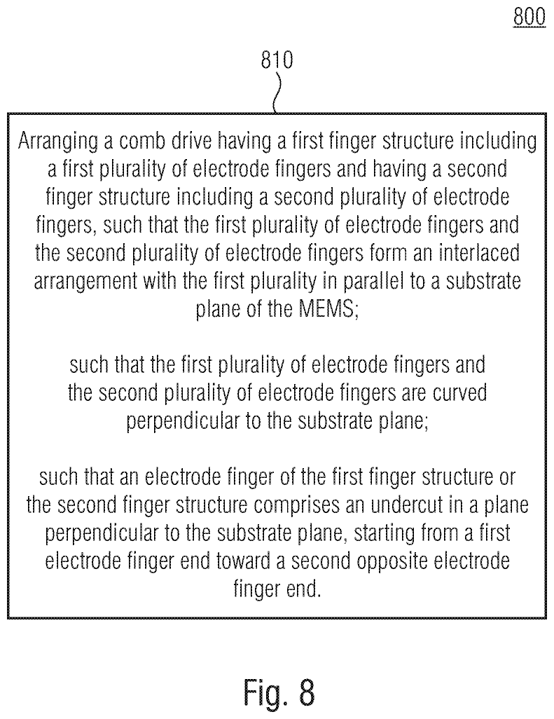

FIG. 8 shows a schematic flow diagram of a method 800 according to an embodiment. The same comprises a step 810, wherein arranging a comb drive having a first finger structure including the first plurality of electrode fingers and having a second finger structure including a second plurality of electrode fingers takes place. This is implemented such that the first plurality of electrode fingers and the second plurality of electrode fingers are curved perpendicular to the substrate plane and such that an electrode finger of the first finger structure or the second finger structure comprises an undercut in a plane perpendicular to the substrate plane, starting from a first electrode finger end toward a second opposite electrode finger end.

Embodiments described herein relate to MEMS devices that can be configured as layer stacks, consisting of at least one substrate layer in which the electrodes and the passive elements are arranged. Further layers relate, for example, to a base, which can also be referred to as handling wafer, and a lid, which can also be referred to as lid wafer. Both lid wafer as well as handling wafer can be connected to the substrate plane via material-fit methods, advantageously bonding, which can result in acoustically sealed gaps within devices. In this gap, which can correspond to a device plane, deformable elements are deformed, in other words, in-plane deformation can take place, for example, triggered by comb drives described herein. This is particularly advantageous for embodiments of the present invention relating to MEMS that are configured as loudspeakers.

The layers can comprise, for example, electrically conductive materials, for example, doped semi-conductor materials and/or metal materials. The layered arrangement of electrically conductive layers allows a simple configuration as electrodes can be formed by selectively removing from the layer, such as for deflectable elements and passive elements. When electrically non-conductive materials are to be arranged, this can take place by means of a layered deposition of these materials by a depositing method.

In the MEMS-based loudspeakers described herein, a normally used conventional membrane is replaced by microbeams, as described, for example, in DE 2017 206 766 A1, such as by using passive beams deflected by electrostatic comb drives. Both the arrangement with the membrane as with the microbeams may need comparatively large displacement during operation. These large deflections have the effect that non-linear effects have a significant influence on the transmission behavior, in particular stress stiffening plays an important part. By the non-linearity, higher harmonics are generated during harmonic excitation, which can result in distortions of the audio signal of the loudspeaker, which is undesirable. With the embodiments described herein, the transmission behavior of the comb drive is modified at large displacements in that the non-linearities can be completely eliminated or can be significantly reduced.

The reduction of the non-linearity can take place such that the non-linear rigidity, i.e., the restoring force against the displacement, is reproduced in dependence on the Coulomb force, i.e., the electrostatic force. When the courses correspond at least approximately, advantageously exactly, the non-linearity is reduced or even extinguished and hence the distortions within the electromagnetic system are at least partly omitted. If the courses approximately correspond, a small residual distortion can remain, which is, however, far below the level of a non-optimized system and still comprises advantages.

The optimization of such an electromechanical system can be discussed based on a comb finger. Normally, straight fingers (elements) are used, which have an almost linear transmission behavior, but are not able to eliminate the non-linearities resulting from the membrane/from the beams. Removing the non-linearity is enabled according to the invention by changing the geometry of the comb finger/deformable element in such that the Coulomb force follows the non-linear restoring force during deflection, see FIG. 2. This can take place, for example, by combining an undercut on the non-clamped side of the deformable element/electrode finger with a broadening of the deformable element at the fixed side with the substrate. The broadening, i.e., an increase of the dimension b along x relates to a width of the electrode at the tip of the finger, such as at the broadest part indicated by y₁. One factor of the broadening has a value of less than factor 2.

The deformable element or the comb drive comprises a wave-shaped recess. Here, the dimensions and in particular the angles are selected as discussed in the context of FIG. 3. So far known solutions describe rectangular or curved microbeams. Due to non-linearities, these geometries can result in distortions of the audio signal. For eliminating or reducing the non-linear transmission portions, according to the invention, the geometry of the microbeam is changed, so that the rigidity of the same depends on the Coulomb force. The microbeams have a curvature and, for example, an undercut on the non-clamped side and allow a broadening at the clamped side. This results in a microbeam that can provide a wave-shaped recess together with an adjacent microbeam.

Aspects of embodiments described herein relate to MEMS devices and methods related thereto. Some embodiments relate to an MEMS having a deformable element or electrode finger, characterized in that the deformable element comprises at least one wave-shaped recess. Some embodiments relate to an MEMS having a deformable element or comb drive, characterized in that the deformable element has a larger extension on the side connected to the substrate than on the freely moveable side.

Some embodiments relate to an MEMS, wherein the angle of the moveable element or the moveable electrode fingers is arranged on the side connected to the substrate at an angle of 0° to 45°, advantageously 1° to 15° and an angle at the freely moveable side in a range of >0° and ≤30°, advantageously at least 0.5° and at most 10°.

Some embodiments of the present invention provide an MEMS converter, wherein the deformable elements or finger structures are embedded in a symmetrical arrangement. Other embodiments provide an MEMS converter, wherein the deformable elements or finger structures are embedded in an asymmetric arrangement.

Some embodiments of the present invention provide a system, wherein the undercut is formed by an approximation by means of steps. Some embodiments of the present invention provide a system, wherein the undercut transitions into a rectangular shape, see FIG. 7b, or originates therefrom, such as at the base of the finger element, see FIG. 7a.

Embodiments of a comb drive described herein can be used for deflecting or moving an element that is moveable for fluidic displacement. This can be both an in-plane movement of a fin structure in the same or a different MEMS plane than the comb drive, but alternatively or additionally, membrane structures can be deflected, such as directly or by using direction-deflecting lever mechanisms.

Although some aspects have been described in the context of an apparatus, it is obvious that these aspects also represent a description of the corresponding method, such that a block or device of an apparatus also corresponds to a respective method step or a feature of a method step. Analogously, aspects described in the context of a method step also represent a description of a corresponding block or detail or feature of a corresponding apparatus.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. MEMS, comprising:
a comb drive with a first finger structure comprising a first plurality of electrode fingers and with a second finger structure comprising a second plurality of electrode fingers that form an interlaced arrangement with the first plurality in parallel to a substrate plane of the MEMS;
wherein the first plurality of electrode fingers and the second plurality of electrode fingers are curved perpendicular to the substrate plane; and
wherein an electrode finger of the first finger structure or the second finger structure comprises an undercut in a plane perpendicular to the substrate plane, starting from a first electrode finger end toward a second opposite electrode finger end.

2. MEMS according to claim 1, wherein main sides of the electrode finders are formed in a curved manner along a direction of the substrate plane.

3. MEMS according to claim 1, wherein the undercut is arranged on at least one side face facing the adjacent electrode finger.

4. MEMS according to claim 1, wherein the comb drive is configured to provide a translational relative movement between the first finger structure and the second finger structure based on an electrostatic force for changing a distance between the first finger structure and the second finger structure in parallel to the substrate plane.

5. MEMS according to claim 1, wherein a projection of the undercut into the substrate plane comprises an essentially rectangular shape; or wherein a projection of the undercut into the substrate plane comprises a combination of several essentially rectangular shapes.

6. MEMS according to claim 1, wherein sides of interdigitating electrode fingers that are facing each other are formed congruently at least within an operating range.

7. MEMS according to claim 1, wherein a side face of an electrode finger of the first finger structure or the second finger structure comprises a concave portion, starting from a first electrode finger end toward a second opposite electrode finger end.

8. MEMS according to claim 7, wherein the concave portion comprises a curvature with a radius that differs from a curvature of the electrode finger at a free end of the electrode finger.

9. MEMS according to claim 7, wherein the concave portion is arranged between a first sidewall portion of the electrode finger that is inclined at a first angle starting from a clamped end of the electrode finger relative to a main extension direction of the electrode finger and a second sidewall portion of the electrode finger that is inclined at a second angle toward a free end of the electrode finger relative to the main extension direction of the electrode finger; wherein the first angle comprises a value of 30° at most and the second angle comprises a value of 45° at most.

10. MEMS according to claim 1, wherein at least one of the electrode fingers comprises a combination of an undercut on a non-clamped side of the electrode finger and a broadening of the electrode finger at a clamped side of the electrode finger opposite to the non-clamped side.

11. MEMS according to claim 10, wherein the at least one electrode finger comprises a larger electrode finger width on the clamped side compared to the non-clamped side.

12. MEMS according to claim 1, wherein a first side face of a first electrode finger of the first finger structure and a second side face of a second electrode finger of the second finger structure facing the first side face are formed congruently within an operating range of the comb drive.

13. MEMS according to claim 1, wherein a wave-shaped recess is arranged between a first side face of a first electrode finger of the first finger structure and a second side face of a second electrode finger of the second finger structure facing the first side face.

14. MEMS according to claim 1, wherein a curvature of curved electrode fingers is adapted to a non-linear rigidity of the comb drive; wherein a curve-based force variation in the comb drive and along a direction of movement of the comb drive compensates a deflection-based rigidity variation of the comb drive within a tolerance range.

15. MEMS according to claim 14, comprising, based on the curvature of curved electrode fingers, a linearized ratio between deflection of the comb drive and generated electrostatic force of the comb drive.

16. MEMS according to claim 1, wherein the first finger structure and the second finger structure form a first structure pair; and the MEMS comprises at least one further structure pair connected in series to the first structure pair along a force direction of the comb drive.

17. MEMS according to claim 1, wherein, starting from a curved area of the electrode fingers, an essentially rectangular area is arranged toward a free end or a clamped end.

18. MEMS according to claim 1, which is formed as a loudspeaker.

19. Method for producing an MEMS, comprising:
arranging a comb drive with a first finger structure comprising a first plurality of electrode fingers and with a second finger structure comprising a second plurality of electrode fingers, such that the first plurality of electrode fingers and the second plurality of electrode fingers form an interlaced arrangement with the first plurality in parallel to a substrate plane of the MEMS;
such that the first plurality of electrode fingers and the second plurality of electrode fingers are curved perpendicular to the substrate plane;
such that an electrode finger of the first finger structure or the second finger structure comprises an undercut in a plane perpendicular to the substrate plane, starting from a first electrode finger end toward a second opposite electrode finger end.
